(19) United States
(12) Patent Application Publication
(10) Pub. No.: US 2015/0060781 A1
(43) Pub. Date: Mar. 5, 2015

(54) DISPLAY APPARATUS AND RELATED MANUFACTURING METHOD

(71) Applicant: Samsung Display Co., Ltd., Yongin-City (KR)

(72) Inventor: Jin-Goo KANG, Yongin-City (KR)

(73) Assignee: Samsung Display Co., Ltd., Yongin-City (KR)

(21) Appl. No.: 14/221,100

(22) Filed: Mar. 20, 2014

(30) Foreign Application Priority Data
Aug. 27, 2013 (KR) 10-2013-0102017

(51) Int. Cl. H01L 27/32; H01L 51/56

(52) U.S. Cl. CPC H01L 27/3258; H01L 27/3248; H01L 51/56
USPC 257/40; 257/59; 257/72; 438/34

(57) ABSTRACT

A display apparatus may include a substrate, a transistor that overlaps the substrate, and a pixel electrode that is electrically connected to the transistor. The display apparatus may further include a first insulation layer disposed between the pixel electrode and the substrate. The display apparatus may further include a second insulation layer. A first portion of the second insulation layer may be disposed between the first insulation layer and the pixel electrode. A second portion of the second insulation layer may overlap the transistor without overlapping the first insulation layer. The display apparatus may further include a pixel-defining layer that partially covers the pixel electrode and exposes an exposed portion of the pixel electrode. The display apparatus may further include a light-emitting layer that overlaps the exposed portion of the pixel electrode and is configured to emit light.

### RELATED APPLICATIONS

This application claims the benefit of Korean Patent Application No. 10-2013-0102017, filed on Aug. 27, 2013, in the Korean Intellectual Property Office, the disclosure of which is incorporated herein in its entirety by reference.

### BACKGROUND

1. Field

The present invention is related to a display apparatus, e.g., an organic light emitting display apparatus, and a method for manufacturing the display apparatus.

2. Description of the Related Art

A display apparatus, such as an organic light emitting display apparatus, may include a pixel defining layer that covers edges of a pixel electrode and exposes a center portion of the pixel electrode. In a manufacturing process of an organic light emitting display apparatus, after the pixel defining layer has been formed, an intermediate layer that includes an emission layer may be formed on the pixel electrode using an inkjet printing method or a nozzle printing method. Typically, a portion of the intermediate layer that overlaps the edges of the pixel electrode may substantially protrude over a portion of the intermediate that overlaps the center portion of the pixel electrode, such that a stepped structure may be formed. The stepped structure may undesirably affect the performance and/or quality of the organic light emitting display apparatus.

### SUMMARY

One or more embodiments of the present invention may be related to a display apparatus (e.g., an organic light emitting display apparatus) that includes a light-emitting layer (or an intermediate layer) with a substantially flat light-emitting surface. The substantially flat light-emitting surface may enable the light-emitting layer to provide light with desirable (e.g., uniform) characteristics. Advantageously, the display apparatus may display images with satisfactory quality.

One or more embodiments of the present invention may be related to a method for manufacturing the display device.

One or more embodiments of the present invention may be related to a display apparatus that may include a substrate, a transistor (e.g., a thin film transistor) that overlaps the substrate, and a pixel electrode that is electrically connected to the transistor. The display apparatus may further include a first insulation layer disposed between the pixel electrode and the substrate. The display apparatus may further include a second insulation layer. A first portion of the second insulation layer may be disposed between the first insulation layer and the pixel electrode. A second portion of the second insulation layer may overlap the transistor without overlapping the first insulation layer. The display apparatus may further include a pixel-defining layer that partially covers the pixel electrode and exposes an exposed portion of the pixel electrode. The display apparatus may further include a light-emitting layer (or intermediate layer) that overlaps the exposed portion of the pixel electrode and is configured to emit light.

The light-emitting layer may include an emission layer and may be disposed between a first portion of the pixel-defining layer and a second portion of the pixel-defining layer. An edge proton of the pixel electrode may be disposed between an edge portion of the first insulation layer and the first portion of the pixel-defining layer

A thickness of the first portion of the pixel-defining layer may be equal to a thickness of a center portion of the light-emitting layer. Each thickness of the thicknesses discussed in the description may be measured in a direction perpendicular to a surface (e.g., bottom surface or top surface) of the substrate.

A third portion of the pixel-defining layer may overlap the transistor. A thickness of the third portion of the pixel-defining layer may be greater than a thickness of the first portion of the pixel-defining layer.

A portion of the pixel-defining layer may be disposed between the pixel electrode and a portion of the light-emitting layer in a direction perpendicular to a surface (e.g., bottom surface or top surface) of the substrate.

A first portion of the pixel-defining layer may be disposed between a center portion of the light-emitting layer and a second portion of the pixel-defining layer. A thickness of the second portion of the pixel-defining layer may be greater than a thickness of the first portion of the pixel-defining layer. The first portion of the pixel-defining layer may overlap at least one of the light-emitting layer and the pixel electrode. The second portion of the pixel-defining layer may overlap at least one of the pixel electrode and the transistor.

The pixel-defining layer may have a tapered structure. The light-emitting layer may have a reversely tapered structure. The reversely tapered structure may match and/or may directly contact the tapered structure.

A viscosity of a material of the first insulation layer may be unequal to a viscosity of a material of the second insulation layer. The viscosity of the material of the first insulation layer and the viscosity of the material of the second insulation layer may be obtained based on a same formula and/or may be obtained using a same measurement method. The viscosity of the material of the first insulation layer may be less than the viscosity of the material of the second insulation layer.

A surface of the second insulation layer may contact the pixel electrode. A surface of the pixel-defining layer may overlap the transistor. A distance between a surface of the substrate and the surface of the second insulation layer is equal to a distance between the surface of the substrate and the surface of the pixel-defining layer. Each of the distances may be measured in a direction perpendicular to a surface (e.g., bottom surface of top surface) of the substrate. The surface of the pixel-defining layer may not directly contact the second insulation layer and may overlap a surface of the pixel-defining layer that directly contacts the second insulation layer.

The display apparatus may include a protective layer that is disposed between the second insulation layer and the substrate. A first portion of the protective layer may be disposed between the transistor and a first portion of the second insulation layer. The first insulation layer may be disposed between a second portion of the second insulation layer and a second portion of the protective layer. A portion of the pixel electrode may be disposed between the first insulation layer and the first portion of the protective layer and may be disposed in a contact hole for electrically connecting to the transistor.

One or more embodiments of the present invention may be related to method for manufacturing a display apparatus. The method may include the following steps: preparing a substrate; forming a transistor that overlaps the substrate and includes a gate electrode; forming a first insulation layer that overlaps the substrate without overlapping the gate electrode; forming a second insulation layer such that a first portion of the second insulation layer overlaps the first insulation layer and such that a second portion of the second insulation layer overlaps the transistor without overlapping the first insulation layer; forming a pixel electrode that overlaps the first insulation layer and is electrically connected to the transistor; forming a pixel-defining layer that partially covers the pixel electrode and exposes an exposed portion of the pixel electrode; and forming a light-emitting layer that overlaps the exposed portion of the pixel electrode and is configured to emit light.

A viscosity of a material of the first insulation layer is unequal to a viscosity of a material of the second insulation layer. The viscosity of the material of the first insulation layer and the viscosity of the material of the second insulation layer may be obtained based on a same formula and/or may be obtained using a same measurement method. The viscosity of the material of the first insulation layer may be less than the viscosity of the material of the second insulation layer.

A surface of the second insulation layer may contact the pixel electrode. A surface of the pixel-defining layer overlaps the transistor. A distance between a surface of the substrate and the surface of the second insulation layer may be equal to a distance between the surface of the substrate and the surface of the pixel-defining layer.

A first portion of the pixel-defining layer may be positioned closer to a center portion of the light-emitting layer than a second portion of the pixel-defining layer. A thickness of the second portion of the pixel-defining layer may be greater than a thickness of the first portion of the pixel-defining layer.

According to one or more embodiments of the present invention, an organic light emitting display apparatus may include the following elements: a substrate having a plurality of pixel regions; a plurality of thin film transistors (TFTs) disposed on the substrate; a plurality of first-type insulation layers (or first insulation layers) respectively disposed at the plurality of pixel regions; a second-type insulation layer (or second insulation layer) disposed to cover the plurality of TFTs and the first insulation layer; a plurality of pixel electrodes located on the second insulation layer, disposed at the plurality of pixel regions, and electrically connected to the plurality of TFTs; and a pixel defining layer covering edges of each of the plurality of pixel electrodes and exposing a center portion of the each pixel electrode.

A first insulation layer may overlap to a center portion of a pixel electrode of the plurality of pixel electrodes.

A material of the first insulation may have a viscosity that is different from a viscosity of a material the second insulation layer.

The viscosity of the material of the first insulation layer may be less than the viscosity of the material of the second insulation layer.

A distance between a surface (e.g., top surface or bottom surface) of the substrate and an upper surface of the second insulation layer that overlaps (and directly contacts) a pixel electrode may be equal to a distance between the surface of the substrate and an upper surface of the pixel defining layer that overlaps a TFT of the TFTs and/or is not disposed at any of the plurality of pixel regions.

The organic light emitting display apparatus may include an intermediate layer that may include an emission layer and may be disposed on the pixel electrode. A portion of the pixel defining layer that overlaps (and directly contacts) the pixel electrode may have a thickness that is substantially equal to a thickness of (a center portion of) the intermediate layer.

According to one or more embodiments of the present invention, a method for manufacturing an organic light emitting display apparatus may include the following steps: preparing a substrate; forming a plurality of thin film transistors (TFTs) on the substrate; forming a plurality of first-type insulation layers (or first insulation layers) on the substrate; forming a second-type insulation layer (or second insulation layer) that covers the plurality of TFTs and the plurality of first insulation layers; forming a plurality of pixel electrodes on the second insulation layer and electrically connecting the plurality of pixel electrodes to the plurality of TFTs; and forming a pixel defining layer that covers edges of each of the plurality of pixel electrodes, exposes a center portion of the each of the plurality of pixel electrodes, and defines a plurality of pixel regions.

The first insulation layers may respectively overlap the center portions of the pixel electrodes, wherein the center portions may be exposed by the pixel defining layer.

The first insulation may be formed using a material having a viscosity that is different from a viscosity of a material used for forming the second insulation layer.

The viscosity of the material of the first insulation layer may be less than the viscosity of the material of the second insulation layer.

A distance between a surface (e.g., top surface or bottom surface) of the substrate and an upper surface of the second insulation layer that overlaps (and directly contacts) a pixel electrode may be equal to a distance between the surface of the substrate and an upper surface of the pixel defining layer that overlaps a TFT of the TFTs and/or is not disposed at any of the plurality of pixel regions.

The method may further include forming an intermediate layer on each of the pixel electrodes. The intermediate layer may include an emission layer that is configured for emitting light. A portion of the pixel defining layer that overlaps (and directly contacts) the pixel electrode may have a thickness that is substantially equal to a thickness of (a center portion of) the intermediate layer.

### BRIEF DESCRIPTION OF THE DRAWINGS

FIG. 1 is a schematic cross-sectional view illustrating a display apparatus, e.g., an organic light emitting display apparatus, according to an embodiment of the present invention.

FIGS. 2 through 5 are schematic cross-sectional views illustrating a method for manufacturing a display apparatus, e.g., an organic light emitting display apparatus, according to an embodiment of the present invention.

### DETAILED DESCRIPTION

Embodiments of the present invention are described with reference to the accompanying drawings. The invention may be embodied in many different forms and should not be construed as being limited to the described embodiments. In the drawings, sizes of components may be exaggerated or reduced for clarity and/or for convenience of description. Embodiments of the present invention are not necessarily limited to the drawings. In the description, the term “and/or” may include any and all combinations of one or more of the associated items. Expressions such as “at least one of,” when preceding a list of elements, may modify the entire list of elements and may not modify the individual elements of the list.

Although the terms “first”, “second”, etc. may be used herein to describe various signals, elements, components, regions, layers, and/or sections, these signals, elements, components, regions, layers, and/or sections should not be limited by these terms. These terms may be used to distinguish one signal, element, component, region, layer, or section from another signal, region, layer, or section. Thus, a first signal, element, component, region, layer, or section discussed below may be termed a second signal, element, component, region, layer, or section without departing from the teachings of the present invention. The description of an element as a “first” element may not require or imply the presence of a second element or other elements. The terms “first”, “second”, etc. may also be used herein to differentiate different categories of elements. For conciseness, the terms “first”, “second”, etc. may represent “first-type (or first-category)”, “second-type (or second-category)”, etc., respectively.

Each thickness of the thicknesses discussed in the description may be measured in a direction perpendicular to a surface (e.g., bottom surface or top surface) of a substrate.

In the description, if a first element, e.g., a layer, region, or component, is referred to as being “on” a second element, the first element may be directly or indirectly contact the second element; for example, an intervening element may be present.

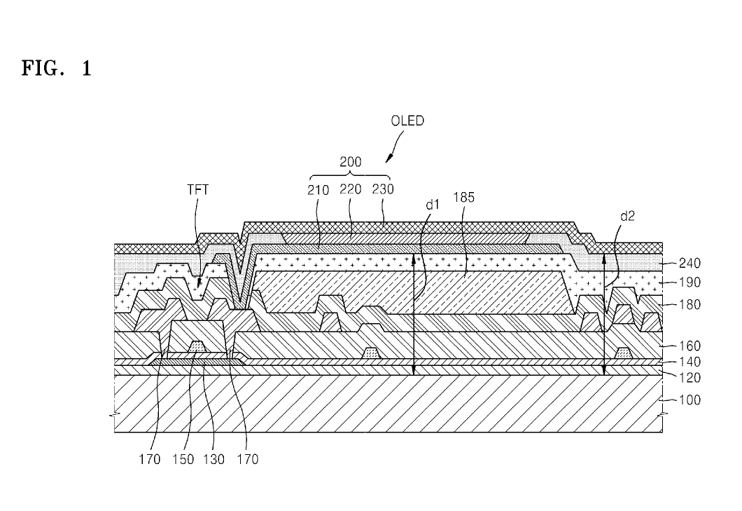

FIG. 1 is a schematic cross-sectional view illustrating a display apparatus, e.g., an organic light emitting display apparatus, according to an embodiment of the present invention. The organic light emitting display apparatus includes a substrate 100, a plurality of thin film transistors (TFTs), a first insulation layer 185, a second insulation layer 190, a plurality of pixel electrodes 210, and a pixel defining layer 240.

The substrate 100 may include a plurality of pixel regions for emitting light and displaying portions of images. The plurality of pixel electrodes 210 may be disposed in the plurality of pixel regions. Peripheral regions that surround the pixel regions may be non-pixel regions for accommodating at least the plurality of TFTs. The substrate 100 may be formed at least one of various materials, such as a glass material, a metal material, or a plastic material.

The plurality of TFTs may be disposed on the substrate 100 in the non-pixel regions. Organic light emitting devices (OLEDs) 200 that include the pixel electrodes 210 may be electrically connected to the TFTs and may be disposed in the pixel regions. In an embodiment, the plurality of pixel electrodes 210 may be electrically connected to the plurality of TFTs through contact holes formed in the second insulation layer 190.

Each of the TFTs includes a semiconductor layer 130, a gate electrode 150, and a source electrode 170, and a drain electrode 171. The semiconductor layer 130 may include at least one of amorphous silicon, polycrystalline silicon, and an organic semiconductor material.

A buffer layer 120 formed of silicon oxide or silicon nitride is disposed on the substrate 100 in order to planarize the surface of the substrate 100 and/or to prevent impurities from infiltrating into the semiconductor layer 130. The semiconductor layer 130 may be located on and may directly contact the buffer layer 120.

The gate electrode 150 is disposed on and insulated from the semiconductor layer 130. The source and drain electrodes 170 may be electrically connected to each other in response to a gate-on signal applied to the gate electrode 150. The gate electrode 150 may have a single-layered or a multi-layered structure and may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode 150 may be formed in consideration of adhesion between adjacent layers, surface flatness of stacked layers, and processability of the structure. A gate insulation layer 140 formed of silicon oxide and/or silicon nitride may be disposed between the semiconductor layer 130 and the gate electrode 150 in order to ensure electrical insulation between the semiconductor layer 130 and the gate electrode 150.

An interlayer insulating layer 160 may be disposed on the gate electrode 150. The interlayer insulating layer 160 may have a single-layered or a multi-layered structure and may include at least one of silicon oxide and silicon nitride.

The source electrode 170 and the drain electrode 171 are disposed on the interlayer insulating layer 160. The source electrode 170 and the drain electrode 171 are electrically connected to the semiconductor layer 130 via contact holes formed in the interlayer insulating layer 160 and the gate insulation layer 140. Each of the source electrode 170 and the drain electrodes 171 may have a single-layered or a multi-layered structure and may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), formed in consideration of electrical conduction properties.

A protective layer 180 may cover the plurality of TFTs to protect the TFTs. The protective layer 180 may be formed of an inorganic material, such as silicon oxide, silicon nitride, or silicon oxynitride. In an embodiment, as illustrated in FIG. 1, the protective layer 180 may be a single layer. In an embodiment, the protective layer 180 may have a multi-layered structure.

A first-type insulation 185 (or first insulation layer 185, for conciseness) may be disposed in each of the pixel regions and may be disposed on the protective layer 180. Each first insulation layer 185 may function as a planarization layer to provide a substantially flat surface for forming and/or accommodating an OLED 200 in the corresponding pixel region. A first insulation layer 185 may function as a planarization layer for providing a substantially flat surface over the protective layer 180 in a pixel region. Referring to FIG. 1, the first insulation layers 185 may be disposed only in the pixel regions, unlike the gate insulation layer 140, the interlayer insulation layer 160, and the protective layer 180 that are formed on an entire surface of the substrate 100. Each first insulation layer 185 may overlap a center portion of a pixel electrode 210, which may be exposed by the pixel defining layer 240. The first insulation layers 185 may substantially planarize the surfaces on which the OLEDs 200 are formed and may substantially overlap the OLEDs 200.

A second-type insulation layer 190 (or second insulation layer 190, for conciseness) may be disposed on the first insulation layer 185 and the protective layer 180. The second insulation layer 190 may function as a planarization layer and/or a protective layer. In an embodiment, as shown in FIG. 1, portions of the second insulation layer 190 may be disposed in the pixel regions where the OLEDs 200 are disposed and may provide a substantially flat surface over the first insulation layers 185 for forming and/or accommodating the pixel electrodes 210 and/or the OLEDs 200.

A dual-layered structure that includes the first insulation layers 185 and the second insulation layer 190 may be formed of, for example, an acryl-based organic material and/or benzocyclobutene (BCB). In an embodiment, a viscosity of a material of the first insulation layers 185 and a viscosity of a material of the second insulation layer 190 may be different from each other. Therefore, the material of the first insulation layers 185 and the material of the second insulation layer 190 may complement each other and cooperate to perform both planarization and filling. Advantageously, the dual-layered structure of the first insulation layers 185 and the second insulation layer 190 may provide both satisfactory flatness characteristics and satisfactory coverage characteristics.

In an embodiment, the viscosity of the material of the first insulation layer 185 may be less than the viscosity of the material of the second insulation layer 190. Each first insulation layer 185, which may have a relatively lower viscosity, may have a desirable planarization characteristic and may provide a satisfactorily flat surface over the protective layer 180 in a pixel region. The second insulation layer 190, which may have a relatively higher viscosity, may satisfactorily fill and/or flatten uneven portions in the protective layer 180 and uneven portions between the protective layer 180 and the first insulation layer 185 near and at borders between non-pixel regions and pixel regions, while providing sufficiently flat surfaces in the pixel regions. Accordingly, desirable (e.g., substantially robust and flat) foundations for forming and/or supporting the OLEDs 200, which include the pixel electrodes 210 and an opposite electrode 230 may be formed. Advantageously, potential short circuit between the pixel electrodes 210 and the opposite electrode 230 may be prevented, and satisfactory quality of the display apparatus may be provided.

Each OLED 200 of the OLEDs 200 may include a pixel electrode 210, a portion of the opposite electrode 230, and an intermediate layer 220 (or light-emitting layer 220). The intermediate layer 220 may be disposed between the pixel electrode 210 and the portion of the opposite electrode 230 and may include an emission layer configured to emit light. The pixel electrode 210 may directly contact the second insulation layer 190.

Openings (or contact holes) that expose the source electrodes 170 and/or the drain electrodes 171 of the TFTs are formed in the second insulation layer 190, the protective layer 180, and/or the first insulation layers 185. The pixel electrodes 210 may be electrically connected to the TFTs by contacting the source electrodes 170 or the drain electrodes 171 via the openings. The plurality of pixel electrodes 210 may be semi-transparent electrodes, transparent electrodes, or reflective electrodes. In an embodiment, the pixel electrodes 210 are semi-transparent electrodes that may be formed of, for example, indium tin oxide (ITO), indium zinc oxide (IZO), ZnO, In₂O₃, indium gallium oxide (IGO), or AZO. In an embodiment, the pixel electrodes 210 may be reflective electrodes that may include a reflective layer formed of Ag, Mg, Al, Pt, Pd, Au, Ni, Nd, Ir, Cr, or an alloy of some of these materials and may include a layer formed of ITO, IZO, ZnO, In2O3, IGO, or AZO. A pixel electrode 210 may have a single layered or multi-layered structure.

A pixel defining layer 240 may be disposed on the second insulation layer 190. The pixel defining layer 240 includes openings that may be positioned in the pixel regions and may expose at least center portions of the pixel electrodes 210 to define pixels. In an embodiment, as shown in FIG. 1, the pixel defining layer 240 may overlap end portions of the pixel electrodes 210 to substantially electrically insulate the opposite electrode 230 from the end portions of the pixel electrodes 210, so as to prevent arcing at the end portions of the pixel electrodes 210. The pixel defining layer 240 may be formed of an organic material, such as polyimide.

In a pixel region, an intermediate layer 220 may be disposed in an opening of the pixel defining layer 240 and may direct contact a center portion of a pixel electrode 210 exposed by the opening. An edge portion of the intermediate layer 220 may overlap an edge portion of the pixel defining layer 240 that is disposed in the pixel region. The edge portion of the pixel defining layer 240 may be disposed between the pixel electrode 210 and the edge portion of the intermediate layer 220, and therefore may affect a height of the edge portion of the intermediate layer 220 relative to a center portion of the intermediate layer 220. A thickness of the edge portion of the pixel defining layer 240 (which is disposed in the pixel region and overlaps the edge portion of the intermediate layer 220) may be relatively thin in comparison with a portion of the pixel defining layer 240 that is disposed in a non-pixel region and/or overlaps (a component of) a TFT. Therefore, the edge portion of the intermediate layer 220 (which overlaps the edge of the pixel defining layer 240) may not protrude over the center portion of the intermediate layer 220, and the intermediate layer 220 may have a substantially light-emission surface. Advantageously, optimal light-emission characteristics of the intermediate layer 220 may be provided.

In an embodiment, the edge portion of the pixel defining layer 240 may have a tapered structure, and the edge portion of the intermediate layer 220 may have a reversely tapered structure that matches the tapered structure of the edge portion of the pixel defining layer 240.

In an embodiment, a first portion of the pixel defining layer 240 is disposed between a center portion of the intermediate layer 220 and a second portion of the pixel defining layer 240. The first portion of the pixel defining layer 240 may overlap the pixel electrode 210 and/or may overlap an edge portion of the intermediate layer 220. The second portion of the pixel defining layer 240 may overlap the pixel electrode 210 and/or may overlap the TFT. The first portion of the pixel defining layer 240 may be thinner than the second portion of the pixel defining layer 240.

A distance d1 between a surface of the substrate 100 and an upper surface of the second insulation layer 190 that contacts a pixel electrode 210 may be substantially equal to a distance d2 between the surface of the substrate 100 and an upper surface of the pixel defining layer 240 that is in a non-pixel region and/or overlaps (a component of) a TFT. Therefore, the upper surface of the second insulation layer 190 (that contacts the pixel electrode 210 and is disposed in a pixel region) and the upper surface of the pixel defining layer 240 in the non-pixel region may be substantially positioned in a same plane that is substantially parallel to the surface of the substrate 100. A thickness of the pixel defining layer 240 in the pixel region may be substantially equal to a thickness of the intermediate layer 220 in the pixel region.

An intermediate layer 220 of an OLED 200 may include one or more low-molecular weight organic materials and/or one or more polymer organic materials. The intermediate layer 220 may have one or more of various materials and/or structures.

In an embodiment, the intermediate layer 220 is formed of a low-molecular organic material. The intermediate layer 220 may include a hole injection layer (HIL), a hole transport layer (HTL), an emission layer (EML), an electron transport layer (ETL), and an electron injection layer (EIL) in a single or multiple-layered structure. Examples of organic materials suitable for forming the intermediate layer 220 may include copper phthalocyanine (CuPc), N,N′-Di(naphthalene-1-yl)-N,N′-diphenyl-benzidine (NPB), and tris-8-hydroxyquinoline aluminum (Alq₃).

In an embodiment, the intermediate layer 220 is formed of a polymer organic material. The intermediate layer 220 may include a structure in which an HTL and an EML are stacked. The HTL may be formed of poly-(2,4)-ethylene-dihydroxy thiophene (PEDOT), and the EML may be formed of one or more polymer organic materials, such as polyphenylene vinylene (PPV) and/or polyfluorene.

The intermediate layer 220 may be disposed in an opening of the pixel defining layer 240 in a pixel region. In the pixel region, a thickness of a portion of the pixel defining layer 240 that contacts the upper surface of the pixel electrode 210 may substantially equal to a thickness of (a center portion of) the intermediate layer 220. Therefore, the pixel defining layer 240 may not substantially protrude over the intermediate layer 220 and may not substantially interfere with the light emitted by the intermediate layer 220.

The opposite electrode 230 may be disposed in and/or may cover both the pixel regions and the non-pixel regions. Portions of the opposite electrode 230 may be members of the OLEDs 200 and may overlap the pixel electrodes 210.

The opposite electrode 230 may be a semi-transparent electrode, a transparent electrode, or a reflective electrode. The opposite electrode 230 may have one or more of various materials and/or structures.

In an embodiment, the opposite electrode 230 is a semi-transparent electrode. The opposite electrode 230 may include a layer formed of one or more metal materials that have a small work function, e.g., Ag, Mg, Al, Pt, Pd, Au, Ni, Nd, Ir, Cr, or an alloy of some of these metal materials. The opposite electrode 230 may include a semi-transparent or transparent conductive layer formed of ITO, IZO, ZnO, or In₂O₃.

In an embodiment, the opposite electrode 230 is a reflective layer. The opposite electrode 230 may include a layer formed of Li, Ca, LiF/Ca, LiF/Al, Al, Ag, Mg, or an alloy of some of these materials.

According to embodiments of the present invention, the intermediate layer 220 may have a substantially flat light-emitting surface, and the pixel-defining layer 240 may not substantially interfere with light emitted by the intermediate layer 220. Advantageously, light-emitting characteristics of the display apparatus may be optimized.

According to embodiments of the present invention, a substantially flat and robust foundation for forming and/or supporting the OLED 200 may be provided, and desirable insulation may be provided. Therefore, potential short circuit between the common electrode 230 and the pixel electrodes 210 may be prevented, and arcing at edges of the pixel electrodes 210 may be prevented. Advantageously, satisfactory quality, reliability, and/or durability of the display apparatus may be provided.

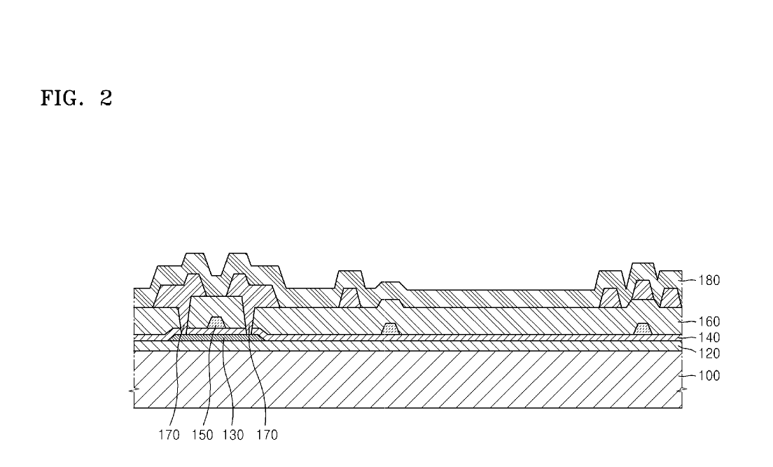

FIGS. 2 through 5 are schematic cross-sectional views illustrating a method for manufacturing a display device, e.g., an organic light emitting display apparatus and/or the display apparatus discussed with reference to FIG. 1, according to an embodiment of the present invention.

Referring to FIG. 2, a substrate 100 is prepared, and a plurality of TFTs may be formed on the substrate 100. Subsequently, a protective layer 180 may be formed on the plurality of TFTs.

In an embodiment, each of the TFTs may include a semiconductor layer 130, a gate electrode 150, a source electrode 170, and a drain electrode 171. The semiconductor layer 130 may include at least one of amorphous silicon, polycrystalline silicon, and an organic semiconductor material. A buffer layer 120 formed of silicon oxide or silicon nitride is formed on the substrate 100 in order to planarize the surface of the substrate 100 and/or in order to prevent impurities from infiltrating into the semiconductor layer 130. The semiconductor layer 130 may be disposed on the buffer layer 120.

The gate electrode 150 is formed on and insulated from the semiconductor layer 130. In order to ensure insulation between the semiconductor layer 130 and the gate electrode 150, a gate insulation layer 140 formed of silicon oxide and/or silicon nitride may be formed between the semiconductor layer 130 and the gate electrode 150.

An interlayer insulation layer 160 may be formed on the gate electrode 150. The interlayer insulation layer 160 may have a single-layered or a multi-layered structure and may include silicon oxide and/or silicon nitride.

The source electrode 170 and drain electrode 171 are formed on the interlayer insulation layer 160. The source electrode 170 and the drain electrode 171 are electrically connected to the semiconductor layer 130 via contact holes formed in the interlayer insulation layer 160 and the gate insulation layer 140. Each of the gate electrode 150, the source electrode 170, and the drain electrode 171 may have a single-layered or a multi-layered structure that may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may be formed in consideration of a conducting property.

The protective layer 180 may cover the plurality of TFTs to protect the TFTs. The protective layer 180 may be formed of an inorganic material, such as silicon oxide, silicon nitride, or silicon oxynitride. In an embodiment, as illustrated in FIG. 2, the protective layer 180 may have single-layered structure. In an embodiment, the protective layer 180 may have a multi-layered structure.

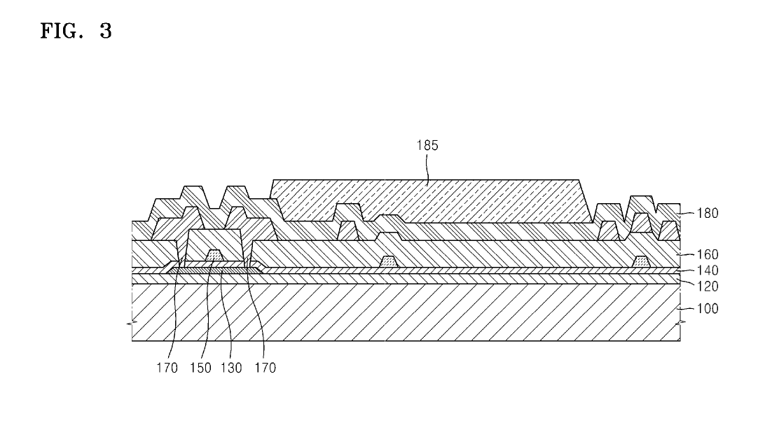

Subsequently, referring to FIG. 3, a first insulation layer 185 may be formed on the protective layer 180. The first insulation layer 185 may have a substantially flat upper surface and may function as a planarization layer. Unlike the gate insulation layer 140, the interlayer insulation layer 160, and the protective layer 180 that are formed on the entire surface of the substrate 100, the first insulation layer 185 may not overlap one or more of the semiconductor layer 130, the gate electrode 150, the source electrode 170, and the drain electrode 171. The first insulation layer 185 may be formed to correspond to a center portion of a subsequently formed pixel electrode 210, which may be exposed by a subsequently formed pixel defining layer 240.

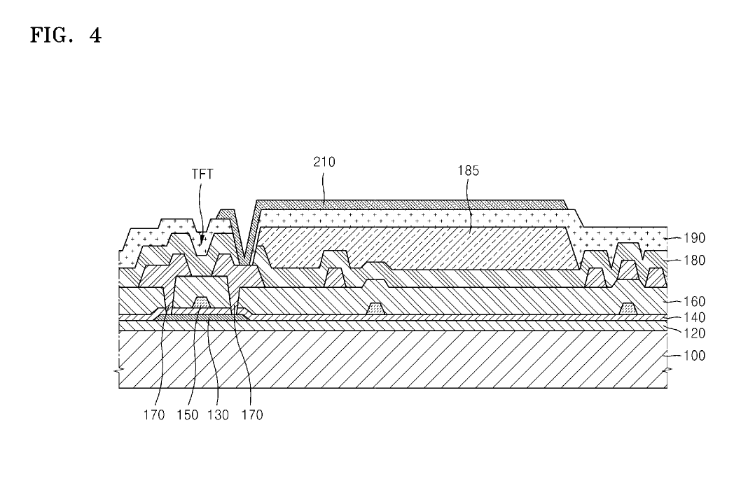

Subsequently, referring to FIG. 4, a second insulation layer 190 is formed to cover the protective layer 180, the plurality of TFTs, and the first insulation layer 185. Subsequently, a plurality of pixel electrodes 210 may be formed on the second insulation layer 190 and may be electrically connected to the plurality of TFTs.

The second insulation layer 190, e.g., a portion of the second insulation layer 190 that is disposed between a pixel electrode 210 and a first insulation layer 185, may have a substantially flat upper surface and may function as a planarization layer.

A dual-layered structure of first insulation layers 185 and the second insulation layer 190 may be formed of, for example, an acryl-based organic material and/or benzocyclobutene (BCB). In an embodiment, a viscosity of a material of the first insulation layer 185 and a viscosity of a material of the second insulation layer 190 may be different from each other. Therefore, the material of the first insulation layers 185 and the material of the second insulation layer 190 may complement each other and cooperate to perform both planarization and filling. Advantageously, the dual-layered structure of the first insulation layers 185 and the second insulation layer 190 may provide both satisfactory flatness characteristics and satisfactory coverage characteristics.

In an embodiment, the viscosity of the material of the first insulation layer 185 may be less than the viscosity of the material of the second insulation layer 190. Each first insulation layer 185, viscosity which may have a relatively lower, may have a desirable planarization characteristic and may provide a satisfactorily flat surface over the protective layer 180. The second insulation layer 190, which may have a relatively higher viscosity, may satisfactorily fill and/or flatten uneven portions in the protective layer 180 and uneven portions between the protective layer 180 and the first insulation layer 185 near and at borders between non-pixel regions and pixel regions, while providing sufficiently flat surfaces in the pixel regions. Accordingly, desirable (e.g., substantially robust and flat) foundations for forming and/or supporting subsequently formed OLEDs 200, which include the pixel electrodes 210 and an opposite electrode 230 may be formed. Advantageously, potential short circuit between the pixel electrodes 210 and a subsequently formed opposite electrode 230 may be prevented, and satisfactory quality of the display apparatus may be provided.

Each OLED 200 of the subsequently formed OLEDs 200 may include the pixel electrode 210, a portion of the opposite electrode 230, and an intermediate layer 220. The intermediate layer 220 may be disposed between the pixel electrode 210 and the portion of the opposite electrode 230 and may include an emission layer. The pixel electrode 210 may be disposed on and may directly contact the second insulation layer 190.

Openings (or contact holes) that expose the source electrodes 170 and/or the drain electrodes 171 of the TFTs are formed in the second insulation 190, the protective layer 180, and/or the first insulation layers 185. The pixel electrodes 210 may be electrically connected to the TFTs by contacting the source electrodes 170 or the drain electrodes 171 via the openings. The plurality of pixel electrodes 210 may be semi-transparent electrodes, transparent electrodes, or reflective electrodes.

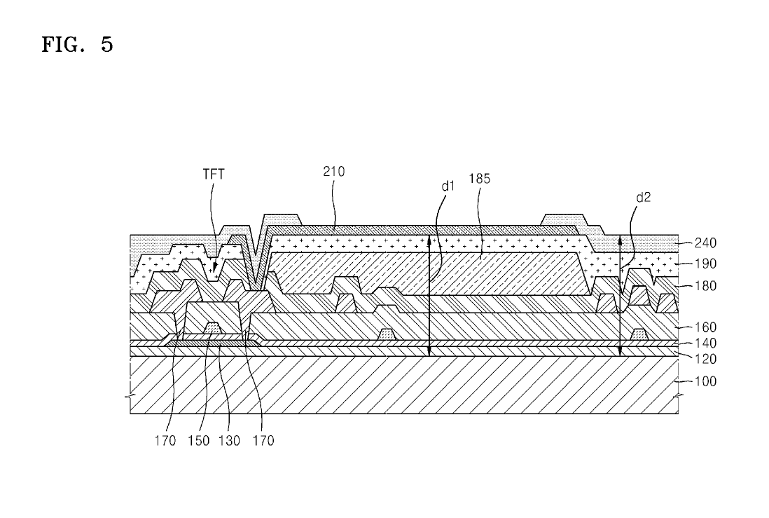

Subsequently, referring to FIG. 5, a pixel defining layer 240 may be formed on the second insulation layer 190 and the pixel electrodes 210. The pixel defining layer 240 may cover edges of the pixel electrodes 210 and may expose center portions of the pixel electrodes 210, thereby defining pixels and/or pixel regions.

A portion of the pixel defining layer 240 may be formed in a non-pixel region, such that the portion of the pixel defining layer 240 may be formed on and directly contact the second insulation layer 190. The portion of the pixel defining layer 240 may overlap (one or more components of) a TFT in a direction perpendicular to a surface (e.g., bottom or top surface) of the substrate 100. A thickness of the edge portion of the pixel defining layer 240 that is disposed in the pixel region may be relatively thin in comparison with a portion of the pixel defining layer 240 that is disposed in a non-pixel region and/or overlaps (a component of) a TFT.

An intermediate layer 220 (illustrated in FIG. 1) that includes a light-emission layer may be formed in an opening of the pixel defining layer 240, may be formed between two portions of the pixel defining layer, may directly contact a pixel electrode 210, and may overlap the edge portion of the pixel defining layer 240. Since the edge portion of the pixel defining layer 240 is substantially thin, the edge portion of the intermediate layer 220 (which overlaps the edge of the pixel defining layer 240) may not protrude over the center portion of the intermediate layer 220, and the intermediate layer 220 may have a substantially light-emission surface. Advantageously, optimal light-emission characteristics of the intermediate layer 220 may be provided.

A distance d1 between a surface of the substrate 100 and an upper surface of the second insulation layer 190 that contacts a pixel electrode 210 may be substantially equal to a distance d2 between the surface of the substrate 100 and an upper surface of the pixel defining layer 240 that is in a non-pixel region and/or overlaps (a component of) a TFT. Therefore, the upper surface of the second insulation layer 190 (that contacts the pixel electrode 210 and is disposed in a pixel region) and the upper surface of the pixel defining layer 240 in the non-pixel region may be substantially positioned in a same plane that is substantially parallel to the surface of the substrate 100. A thickness of the pixel defining layer 240 in the pixel region may be substantially equal to a thickness of the intermediate layer 220 in the pixel region.

The intermediate layer 220 may include one or more low-molecular weight organic materials and/or one or more polymer organic materials. The intermediate layer 220 may have one or more of various materials and/or structures.

In an embodiment, the intermediate layer 220 is formed of a low-molecular organic material. The intermediate layer 220 may include a hole injection layer (HIL), a hole transport layer (HTL), an emission layer (EML), an electron transport layer (ETL), and an electron injection layer (EIL) in a single or multiple-layered structure.

In an embodiment, the intermediate layer 220 is formed of a polymer organic material. The intermediate layer 220 may include a structure in which an HTL and an EML are stacked.

The intermediate layer 220 may be disposed in an opening of the pixel defining layer 240 in a pixel region. In the pixel region, a thickness of a portion of the pixel defining layer 240 that contacts the upper surface of the pixel electrode 210 may substantially equal to a thickness of (a center portion of) the intermediate layer 220. Therefore, the pixel defining layer 240 may not substantially protrude over the intermediate layer 220 and may not substantially interfere with the light emitted by the intermediate layer 220.

An opposite electrode 230 (illustrated in FIG. 1) may be formed on the intermediate layer 220 and the pixel defining layer 240. The opposite electrode 230 may be disposed in and/or may cover both the pixel regions and the non-pixel regions. Portions of the opposite electrode 230, intermediate layers 220, and pixel electrodes 210 may form OLEDs 200 (illustrated in FIG. 1). The opposite electrode 230 may be a semi-transparent electrode, a transparent electrode, or a reflective electrode. The opposite electrode 230 may have one or more of various structures and/or materials.

According to embodiments of the present invention, the intermediate layer 220 may have a substantially flat light-emitting surface, and the pixel-defining layer 240 may not substantially interfere with light emitted by the intermediate layer 220. Advantageously, light-emitting characteristics of the display apparatus may be optimized.

According to embodiments of the present invention, a substantially flat and robust foundation for forming and/or supporting the OLED 200 may be provided, and desirable insulation may be provided. Therefore, potential short circuit between the common electrode 230 and the pixel electrodes 210 may be prevented, and arcing at edges of the pixel electrodes 210 may be prevented. Advantageously, satisfactory quality, reliability, and/or durability of the display apparatus may be provided.

The embodiments described above should be considered illustrative and not limiting. Descriptions of features or aspects in embodiment may be applicable to one or more other embodiments.

While embodiments of the present invention have been described with reference to the figures, it will be understood by those of ordinary skill in the art that various changes in form and details may be made without departing from the spirit and scope of the present invention as defined by the following claims.

What is claimed is:

1. An organic light emitting display apparatus comprising:
a substrate having a plurality of pixel regions;
a plurality of thin film transistors (TFTs) disposed on the substrate;
a first insulation layer disposed on the plurality of pixel regions of the substrate;
a second insulation layer disposed to cover the plurality of TFTs and the first insulation layer;
a plurality of pixel electrodes located on the second insulation layer to correspond to the plurality of pixel regions so as to be electrically connected to the plurality of TFTs; and
a pixel defining layer covering edges of each of the plurality of pixel electrodes so as to expose a center portion of the each pixel electrode.

2. The organic light emitting display apparatus of claim 1, wherein the first insulation layer is disposed to correspond to center portions of the plurality of pixel electrodes, wherein the center portions of the pixel electrodes are exposed by the pixel defining layer.

3. The organic light emitting display apparatus of claim 1, wherein the first insulation has a viscosity that is different from a viscosity of the second insulation unit.

4. The organic light emitting display apparatus of claim 3, wherein the viscosity of the first insulation layer is less than the viscosity of the second insulation layer.

5. The organic light emitting display apparatus of claim 1, wherein a distance between a surface of the substrate facing the pixel electrodes and an upper surface of the second insulation layer in each of the plurality of pixel electrodes is the same as a distance between the surface of the substrate facing the pixel electrodes and an upper surface of the pixel defining layer in a region other than the plurality of pixel regions.

6. The organic light emitting display apparatus of claim 1, further comprising an intermediate layer including an emission layer disposed on the pixel electrodes,
wherein a stepped portion between the upper surface of the pixel electrodes and the upper surface of the pixel defining layer is the same as a thickness of the intermediate layer.

7. A method of manufacturing an organic light emitting display apparatus, the method comprising:
preparing a substrate having a plurality of pixel regions;
forming a plurality of thin film transistors (TFTs) on the substrate;
forming a first insulation layer on the plurality of pixel regions of the substrate;
forming a second insulation layer covering the plurality of TFTs and the first insulation layer;
forming a plurality of pixel electrodes on the second insulation layer to correspond to the plurality of pixel regions so as to be electrically connected to the plurality of TFTs; and
forming a pixel defining layer covering edges of each of the plurality of pixel electrodes so as to expose a center portion of the each of the plurality of pixel electrodes.

8. The method of claim 7, wherein the forming of the first insulation layer comprises forming the first insulation layer to correspond to the center portions of the plurality of pixel electrodes, wherein the center portions are exposed by the pixel defining layer.

9. The method of claim 7, wherein the first insulation has a viscosity that is different from a viscosity of the second insulation unit.

10. The method of claim 9, wherein the viscosity of the first insulation layer is less than the viscosity of the second insulation layer.

11. The method of claim 7, wherein a distance between a surface of the substrate facing the pixel electrodes and an upper surface of the second insulation layer in each of the plurality of pixel electrodes is the same as a distance between the surface of the substrate facing the pixel electrodes and an upper surface of the pixel defining layer in a region other than the plurality of pixel regions.

12. The method of claim 7, further comprising forming an intermediate layer including an emission layer on the pixel electrodes,
wherein a stepped portion between the upper surface of the pixel electrodes and the upper surface of the pixel defining layer is the same as a thickness of the intermediate layer

13. A display apparatus comprising:
a substrate;
a transistor overlapping the substrate;
a pixel electrode electrically connected to the transistor;
a first insulation layer disposed between the pixel electrode and the substrate;
a second insulation layer, a first portion of the second insulation layer being disposed between the first insulation layer and the pixel electrode, a second portion of the second insulation layer overlapping the transistor without overlapping the first insulation layer;
a pixel-defining layer partially covering the pixel electrode and exposing an exposed portion of the pixel electrode; and
a light-emitting layer overlapping the exposed portion of the pixel electrode and configured to emit light.

14. The display apparatus of claim 13, wherein a thickness of the first portion of the pixel-defining layer is equal to a thickness of a center portion of the light-emitting layer.

15. The display apparatus of claim 13, wherein a viscosity of a material of the first insulation layer is unequal to a viscosity of a material of the second insulation layer, the viscosity of the material of the first insulation layer and the viscosity of the material of the second insulation layer being based on a same formula.

16. The display apparatus of claim 15, wherein the viscosity of the material of the first insulation layer is less than the viscosity of the material of the second insulation layer.

17. The display apparatus of claim 13, wherein a surface of the second insulation layer contacts the pixel electrode, wherein a surface of the pixel-defining layer overlaps the transistor, and wherein a distance between a surface of the substrate and the surface of the second insulation layer is equal to a distance between the surface of the substrate and the surface of the pixel-defining layer.
